(19) United States
(12) Patent Application Publication
(10) Pub. No.: US 2018/0254239 A1
(43) Pub. Date: Sep. 6, 2018

(54) FORMING METAL CAP LAYER OVER THROUGH-GLASS-VIAS (TGVs)

(71) Applicant: GLOBALFOUNDRIES Inc., Grand Cayman (KY)

(72) Inventors: Vijay SUKUMARAN, San Jose, CA (US); Ivan Junju HUANG, Pleasanton, CA (US); Saket CHADDA, San Jose, CA (US); Elavarasan T. PANNERSELVAM, Milpitas, CA (US); Chok W. HO, Milpitas, CA (US)

(21) Appl. No.: 15/446,109

(22) Filed: Mar. 1, 2017

(51) Int. Cl. H01L 23/498; H01L 21/48

(52) U.S. Cl. CPC H01L 23/49827; H01L 23/49838; H01L 23/49866; H01L 21/486

(57) ABSTRACT

Methods for reliable interconnect structures between thin metal capture pads and TGV metallization and resulting devices are provided. Embodiments include forming a TGV in a glass substrate; filling with metal conductive paste; forming a metal layer on top and bottom surfaces of the substrate; patterning the metal layer, leaving at least a portion over the TGV top surface and an area surrounding the TGV; forming a dielectric layer on the metal layer and on the substrate top and bottom surfaces; patterning the dielectric layer, including exposing the metal layer over the TGV top surface and the area surrounding the TGV; forming a second metal layer on the dielectric layer and on the exposed portion of the first metal layer over the TGV top surface and the area surrounding the TGV; patterning the second metal layer exposing the dielectric layer; and forming a third metal layer on the second metal layer.

### TECHNICAL FIELD

The present disclosure relates to the manufacture of semiconductor devices, such as integrated circuits (ICs). The present disclosure is particularly applicable to forming interconnect structures for through-glass-vias (TGVs) in a glass substrate.

### BACKGROUND

As ICs continue to decrease in size as a consequence of market demand, metal interconnects through glass substrates, for example, TGVs filled with metal conductive paste are being used to electrically connect circuitry above and below the substrate. However, it is difficult to achieve a reliable connection between the thin metal capture pads and metallization inside a TGV for various reasons, such as, (a) the incoming topography and recess of the metal inside the TGV after a paste fill, (b) the thin metal lines around the perimeter of the TGV snapping off easily due to stress induced from thermal coefficient of expansion (TCE) mismatch between glass, aluminum, and the via fill material, resulting in electrical opens, and (c) thicker metal deposited in a single layer increasing stress and introducing process complexity (e.g., increased profile height, isotropic etching, etc.).

A need therefore exists for methodology enabling formation of a reliable interconnect structure for TGVs and the resulting device.

### SUMMARY

An aspect of the present disclosure is a method for forming plural metal layers over a TGV.

Another aspect of the present disclosure is a method for forming an electroless nickel immersion gold (ENIG) layer over a TGV.

Another aspect of the present disclosure is a device including plural metal layers over a TGV.

Another aspect of the present disclosure is a device including an ENIG layer over a TGV.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a TGV in a glass substrate; filling the TGV with a metal conductive paste; forming a first metal layer on a top surface and a bottom surface of the glass substrate; patterning the first metal layer, leaving at least a portion over a top surface of the TGV and an area surrounding the TGV; forming a dielectric layer on the first metal layer and on the top and bottom surfaces of the glass substrate; patterning the dielectric layer, including exposing the first metal layer over the top surface of the TGV and the area surrounding the TGV; forming a second metal layer on the dielectric layer and on the exposed portion of the first metal layer over the top surface of the TGV and the area surrounding the TGV; patterning the second metal layer to expose the dielectric layer; and forming a third metal layer on the second metal layer.

Another aspect includes ashing prior to forming the first metal layer. Other aspects include forming the first metal layer of aluminum (Al) or aluminum copper (AlCu) to a thickness of 0.3 micrometers (μm) to 5 μm. Further aspects include forming the dielectric layer to a thickness of 0.5 μm to 5 μm. Additional aspects include forming and patterning a second dielectric layer on the second metal layer prior to forming the third metal layer. Other aspects include forming the metal conductive paste of a copper-silver (Cu—Ag) paste.

Another aspect of the present disclosure include forming a TGV in a glass substrate; filling the TGV with a metal conductive paste; forming a metal layer on a top surface and a bottom surface of the glass substrate; patterning the metal layer, leaving at least a portion over a top surface of the TGV and an area surrounding the TGV; forming a dielectric layer on the metal layer and on the top and bottom surfaces of the glass substrate; patterning the dielectric layer, including exposing the metal layer over the top surface of the TGV and the area surrounding the TGV; and forming an ENIG layer on the metal layer over the top surface of the TGV and the area surrounding the TGV.

Another aspect includes ashing prior to forming the metal layer. Further aspects include forming the metal layer of Al or AlCu to a thickness of 0.5 μm to 2 μm. Additional aspects include Al or AlCu zincation prior to forming the ENIG layer. Other aspects include forming the dielectric layer to a thickness of 0.5 μm to 5 μm. Further aspects include forming the metal conductive paste of a Cu—Ag paste.

A further aspect of the present disclosure is a device including: a TGV filled with a metal conductive paste in a glass substrate; a patterned first metal layer on a top surface and a bottom surface of the glass substrate, including at least a portion over a top surface of the TGV and an area surrounding the TGV; a patterned dielectric layer on the first metal layer and the top surface and bottom surface of the glass substrate, the patterned dielectric layer including an opening over the top surface of the TGV and the area surrounding the TGV, exposing the first metal layer; and a second metal layer and a third metal layer or an ENIG layer on the first metal layer.

Aspects of the device include the first metal layer including Al and having a thickness of 0.3 μm to 5 μm and the second and third metal layers are formed on the first metal layer. Other aspects include the second and third metal layers each having a thickness of 0.3 μm to 5 μm.

Another aspect include the second and third metal layers or the ENIG layer formed over a bottom surface of the TGV and the area surrounding the TGV. Other aspects include the ENIG layer formed on the first metal layer, and the first metal layer includes zincated Al or zincated AlCu. Additional aspects include the first metal layer having a thickness of 0.5 μm to 2 μm. A further aspect includes the ENIG layer having a thickness of 1 μm to 2 μm. Additional aspect includes an ENIG layer formed over the second and third metal layers either on the top or a bottom surface of the TGV.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1K schematically illustrate a process flow for forming multiple metal layers over a TGV, in accordance with an exemplary embodiment;

FIGS. 2A through 2I schematically illustrate a process flow for forming an ENIG layer over a TGV, in accordance with an exemplary embodiment;

FIGS. 3A to 3D are different embodiments of metal layers over a wide surface of a TGV, in accordance with exemplary embodiments; and

FIGS. 4A to 4D are different embodiments of metal layers over a narrow surface of a TGV, in accordance with exemplary embodiments.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of inferior TGV connection attendant upon recessing metal inside a TGV and depositing a single thick layer of metal over the TGV. In accordance with embodiments of the present disclosure, plural thin metal layers are formed over the TGV or an ENIG layer is formed over the TGV which penetrates through AlCu over the TGV and contacts the metal particles inside the TGV. The final metal layer reinforces the connections between AlCu and non-sintered Cu/Ag particles inside the TGV, thereby improving the electrical connection and reliability of TGVs.

Methodology in accordance with embodiments of the present disclosure includes forming a TGV in a glass substrate and filling with a metal conductive paste. Then, a first metal layer is formed on a top surface and a bottom surface of the glass substrate. The first metal layer is patterned, leaving at least a portion over a top surface of the TGV and an area surrounding the TGV. Next, a dielectric layer is formed on the first metal layer and on the top and bottom surfaces of the glass substrate. Subsequently, the dielectric layer is patterned, including exposing the first metal layer over the top surface of the TGV and the area surrounding the TGV. Then, a second metal layer is formed on the dielectric layer and on the exposed portion of the first metal layer over the top surface of the TGV and the area surrounding the TGV. Subsequently, the second metal layer is patterned to expose the dielectric layer, and a third metal layer is formed on the second metal layer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

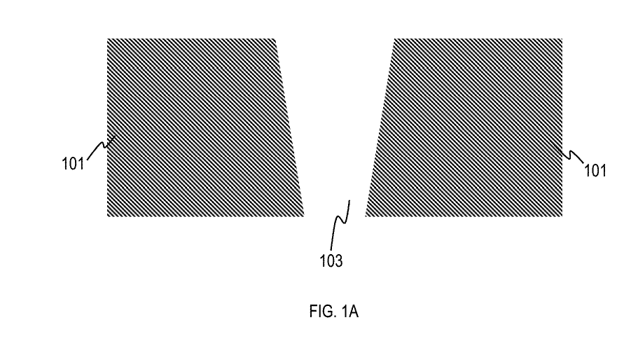

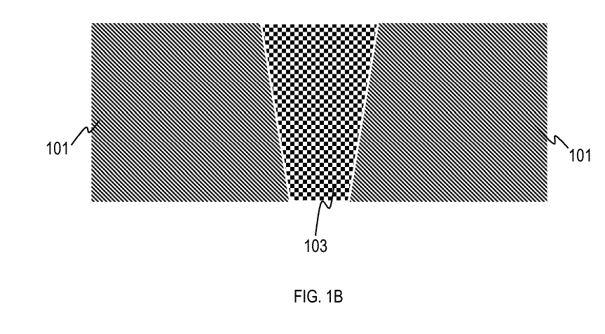

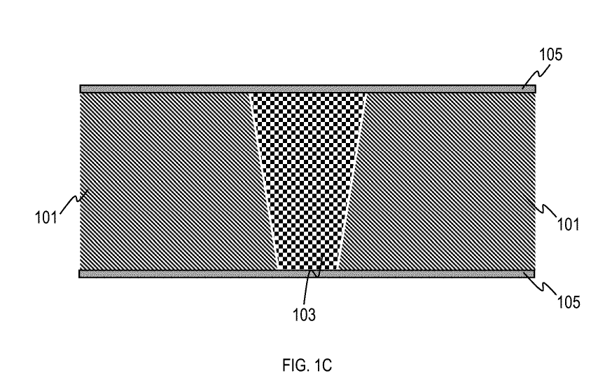

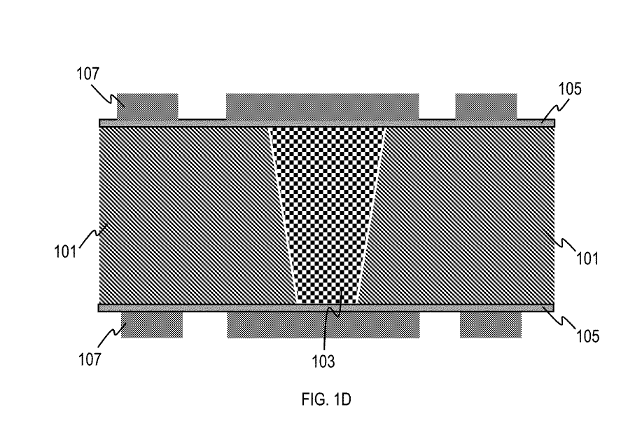

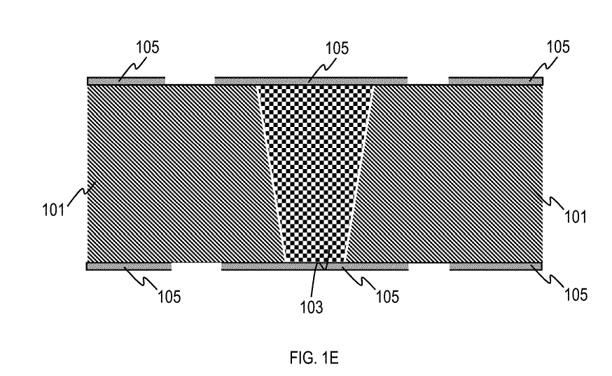

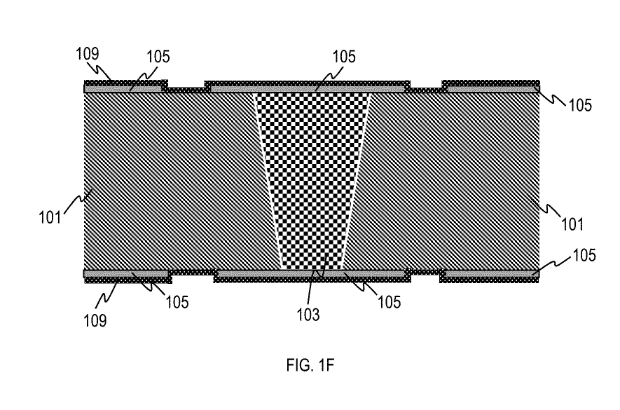

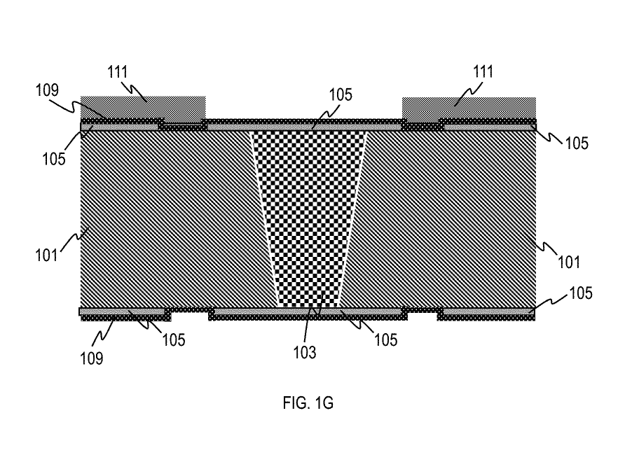

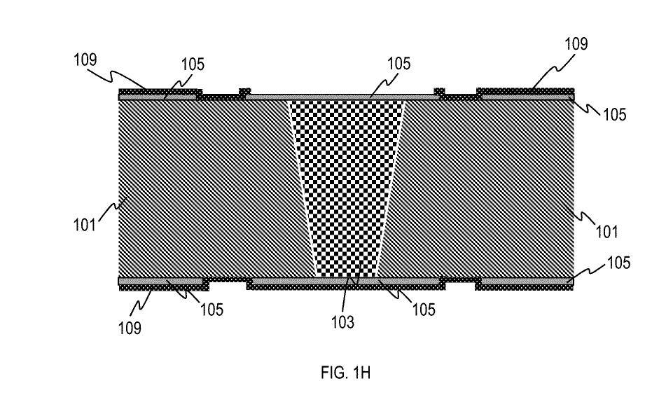

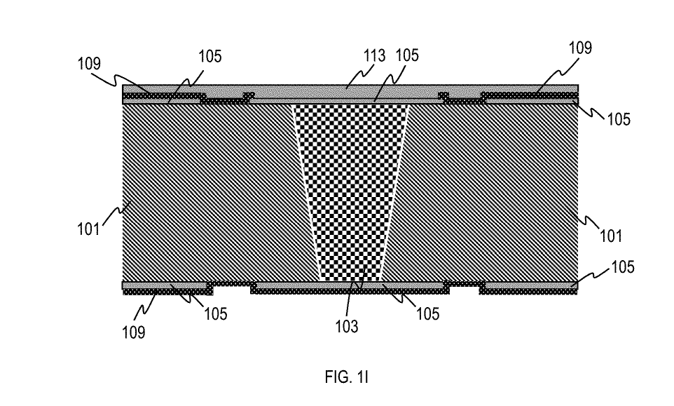

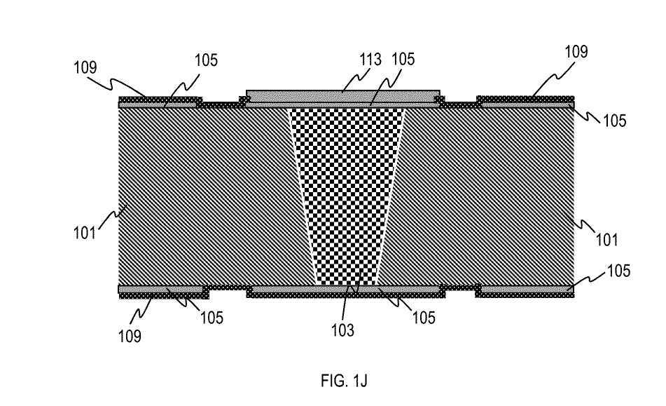

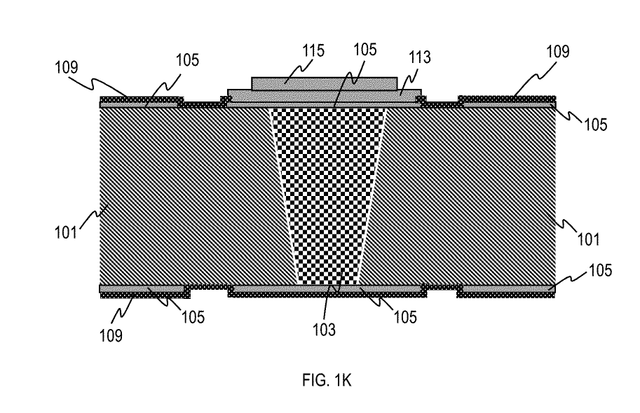

FIGS. 1A through 1K schematically illustrate a process flow for forming multiple metal layers over a TGV, in accordance with an exemplary embodiment. Adverting to FIG. 1A, a TGV 103 is formed in a glass substrate 101. The glass substrate 101 includes any glass type (e.g., borosilicate glass, boro-aluminosilicate glass, soda-lime glass, photodefinable glass, etc.) having a thickness of 50 μm to 500 μm. In addition, the glass substrate 101 can also be extended beyond glass to other substrates with through holes, such as, silicon (Si), gallium arsenide (GaAs), silicon germanium (SiGe), organic, or metal (e.g., stainless steel). The TGV 103 can have a trapezoidal cross-section having a small end width of 10 μm to 95 μm and a large end width of 15 μm to 100 μm or a ‘X’ shaped cross-section with top and bottom width of 15 μm to 100 μm and a center width of 10 μm to 95 μm. The TGV 103 can also be square shaped or rectangular shaped having a width of 10 μm to 100 μm.

In FIG. 1B, the TGV 103 is filled with a metal conductive paste by way of a process similar to a screen printing process. The metal conductive paste includes a Cu—Ag paste, a silver (Ag) paste, a carbon (C) paste, a graphite paste, a nickel (Ni) paste, a brass paste, a gold (Au) paste, a platinum (Pt) paste, an iron (Fe) paste or a paste of other metal materials. A plasma ash process such as O₂ or CF₄ or forming gas (hydrogen (H₂) plus nitrogen (N₂)) plasma is performed over the TGV 103 after paste fill and prior to a first metal deposition, to remove some of the epoxy within the TGV 103 and exposes the Cu/Ag particles. This process also creates topography over the TGV 103 prior to metal deposition. The gas plasma achieves a good connection between the thin Al and the Cu—Ag paste.

Next, in FIG. 1C, a metal layer 105 is formed to a thickness of 0.3 μm to 5 μm on a top surface and a bottom surface of the glass substrate 101. The metal layer 105 includes Al, AlCu, copper (Cu), titanium (Ti), titanium tungsten (TiW), titanium copper (TiCu), or other materials. The metal layer 105 is deposited by sputtering or by laminating thin sheets of metal such as Al directly on the glass substrate 101 using adhesion promoters or by electroplating metal such as Cu. The thickness of the metal layer 105 is not uniform over the TGV due to incoming topography created by the plasma and the TGV paste fill process.

In FIG. 1D, a photoresist 107 is formed on the metal layer 105 on top and bottom surfaces of the TGV 103. Then, in FIG. 1E, the metal layer 105 is patterned, thereby leaving at least a portion of the metal layer 105 over the top and bottom surfaces of the TGV 103 and an area surrounding the TGV 103. Next, the photoresist 107 is removed. As illustrated in FIG. 1F, a dielectric layer 109 is formed by plasma enhanced chemical vapor deposition (PECVD) of silicon dioxide (SiO₂) to a thickness of 0.5 μm to 5 μm on the metal layer 105 and on the top and bottom surfaces of the glass substrate 101. Alternatively, dry film lamination of organic dielectric/ polymers or electrodeposition of polymers can be used for formation of the dielectric layer 109.

Adverting to FIG. 1G, a photoresist 111 is formed on the first dielectric layer 109 on the top and bottom surfaces of the glass substrate 101 (but shown only on top for illustrative convenience). Next, in FIG. 1H, the dielectric layer 109 is patterned on top and bottom surfaces of the TGV 103, exposing the metal layer 105 over the top surface of the TGV 103 and the area surrounding the TGV 103. Then, the photoresist 111 is removed. Next, in FIG. 1I, a second metal layer 113 is formed to a thickness of 0.3 to 5 μm on the dielectric layer 109 and on the exposed portion of the metal layer 105 over the top surface of the TGV 103 and the area surrounding the TGV 103. The second metal layer 113 includes Al, AlCu, Cu, Ti, TiW, TiCu, or other materials. The second metal layer 113 is deposited by sputtering or by laminating thin sheets directly on the dielectric layer 109 and on the exposed portion of the metal layer 105 using adhesion promoters or by electroplating.

In FIG. 1J, a photoresist is formed on the second metal layer 113 (not shown for illustrative convenience), and the second metal layer 113 is patterned to expose the dielectric layer 109. Next, the photoresist is removed. Adverting to FIG. 1K, a second dielectric layer is formed to a thickness of 0.5 to 5 μm on the second metal layer 113 and the dielectric layer 109 (not shown for illustrative convenience) and patterned to expose the second metal layer 113 over the TGV 103. Alternatively, the second dielectric layer may be omitted. Subsequently, a third metal layer 115 is formed either using a process and material similar to metal layers 105 and 115 or by an electroless deposition technique (nickel gold) on the second metal layer 113. The third metal layer 115 is formed to a thickness of 0.3 to 5 μm and may be the final metal layer. However, the number of metal layers is not limited to three; there may be as few as two layers or four to six layers. These three metal layers each have a line-width of 1 μm to 50 μm or higher. The third metal layer 115 penetrates through AlCu (about 2 μm or less) over the TGV and contacts the metal particles (Cu/Ag) inside the TGV. The third metal layer 115 reinforces the connections between AlCu and non-sintered Cu/Ag particles thereby improving the electrical connection and reliability of TGV 103. Although described as being on the top surface of the TGV, the second metal layer 113 and the third metal layer 115 can be formed on both the top and the bottom surfaces of the TGV 103.

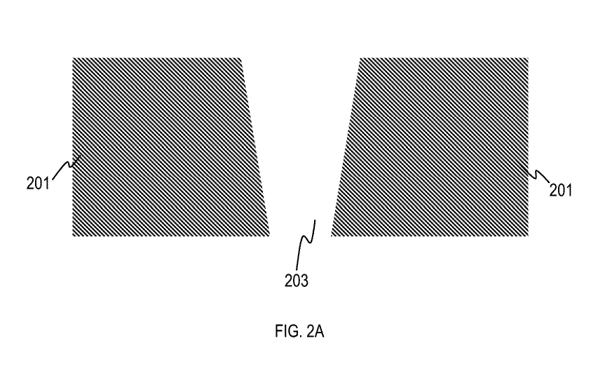

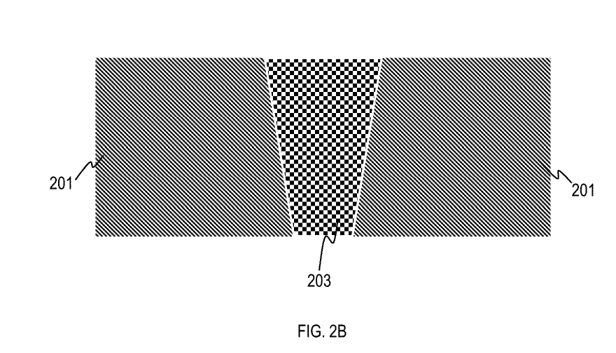

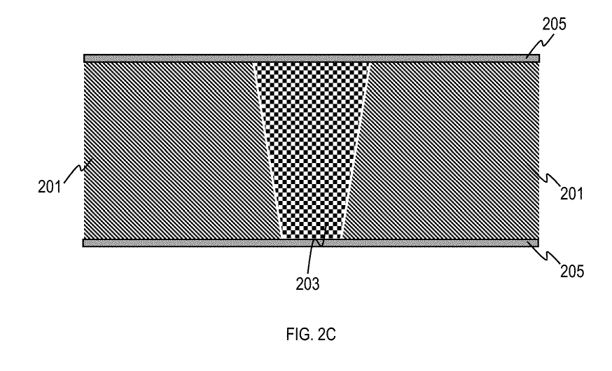

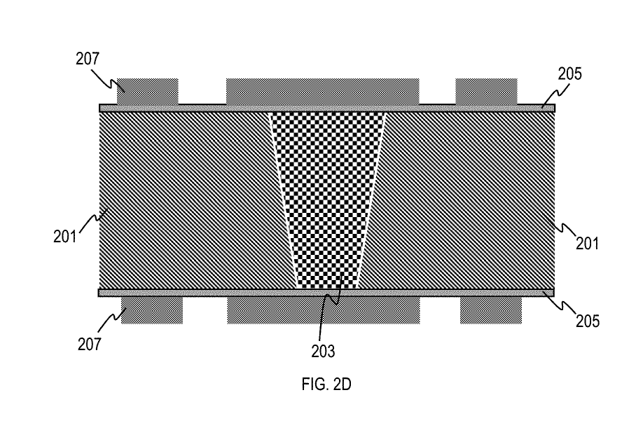

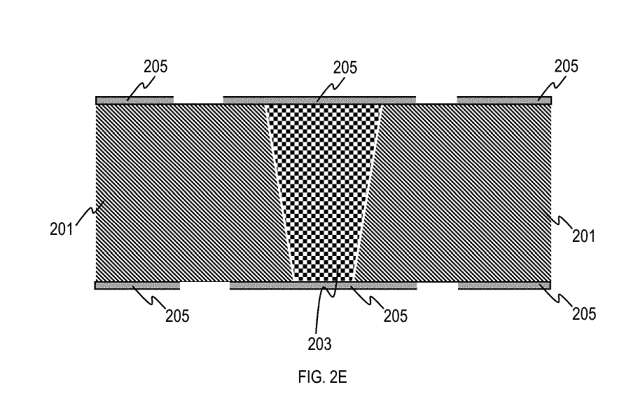

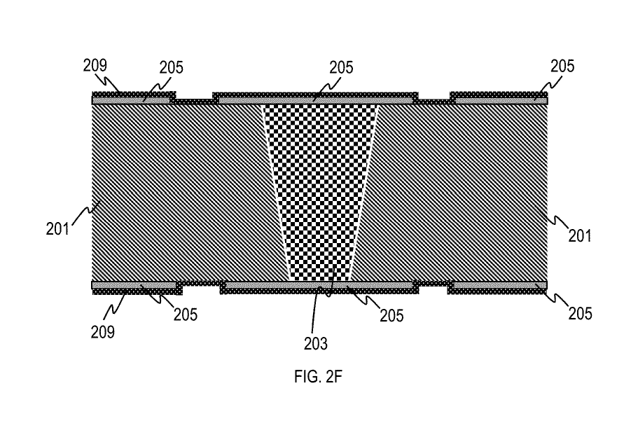

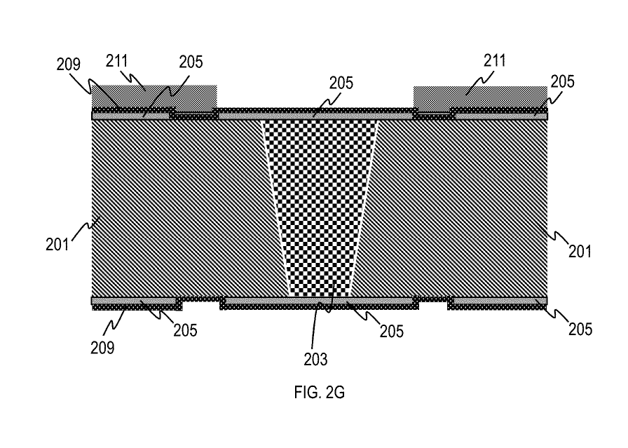

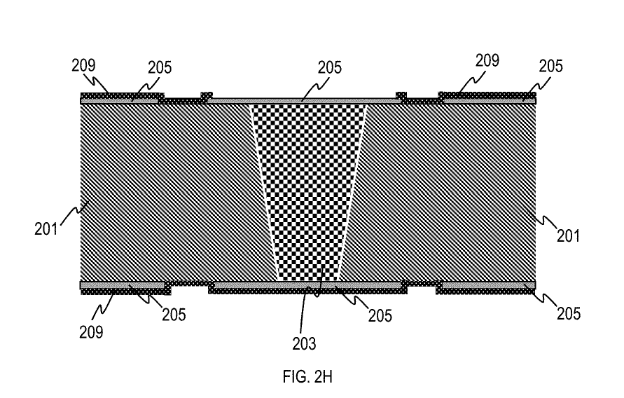

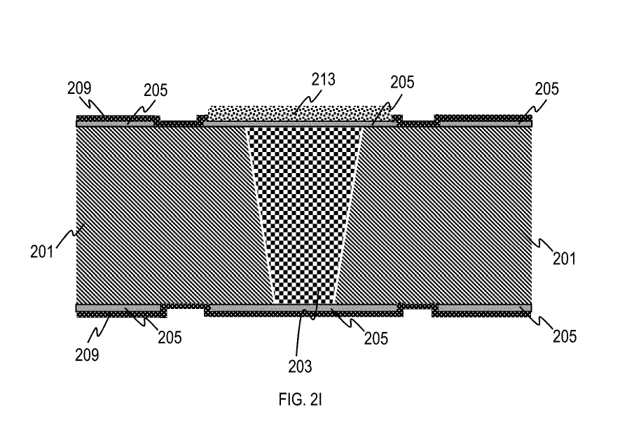

FIGS. 2A through 21 schematically illustrate a process flow for forming an ENIG layer over a TGV, in accordance with an exemplary embodiment. Adverting to FIG. 2A, a TGV 203 is formed in a glass substrate 201. The glass substrate 201 includes any glass type (e.g., borosilicate glass, boro-aluminosilicate glass, soda-lime glass, photodefinable glass, etc.) having a thickness of 50 μm to 500 μm. In addition, the glass substrate 201 can also be extended beyond glass to other substrates with through holes, such as, Si, GaAs, SiGe, organic, or metal (e.g., stainless steel). The TGV 203 can have a trapezoidal cross-section having a small end width of 10 μm to 95 μm and a large end width of 15 μm to 100 μm or an ‘X’ shaped cross-section with a top and bottom width of 15 μm to 100 μm and a center width of 10 μm to 95 μm. The TGV 203 can alternatively have a square shaped or rectangular shaped cross-section with a width of 10 μm to 100 μm.

In FIG. 2B, the TGV 203 is filled with a metal conductive paste by way of a process similar to a screen printing process. The metal conductive paste includes a Cu—Ag paste, an Ag paste, a C paste, a graphite paste, a Ni paste, a brass paste, an Au paste, a Pt paste, a Fe paste or a paste of other metal materials. A plasma ash process such as O₂ or CF₄ or forming gas is performed over the TGV after paste fill and prior to a first metal deposition, to remove some of the epoxy within the TGV and expose the Cu/Ag particles. The process also creates topography over the TGV prior to metal deposition.

Next, in FIG. 2C, a metal layer 205 is formed to a thickness of 0.3 μm to 5 μm on a top surface and a bottom surface of the glass substrate 201. The metal layer 205 includes Al or AlCu, Cu, Ti, TiW, TiCu, or other materials. The metal layer 205 is deposited by sputtering or by laminating thin sheets of Al directly on the glass substrate 201 using adhesion promoters or by electroplating a metal such as Cu. The thickness of the metal layer 205 is not uniform over the TGV due to incoming topography created by plasma and the TGV paste fill process.

In FIG. 2D, a photoresist 207 is formed on the metal layer 205. Then, in FIG. 2E, the metal layer 205 is patterned, thereby leaving at least a portion of the metal layer 205 over the top and bottom surfaces of the TGV 203 and an area surrounding the TGV 203. Next, the photoresist 207 is removed. As illustrated in FIG. 2F, a dielectric layer 209 is formed by PECVD of SiO₂ to a thickness of 0.5 μm to 5 μm on the metal layer 205 and on the top and bottom surfaces of the glass substrate 201. Alternatively, dry film lamination of organic dielectric/ polymers or electrodeposition of polymers can be used for deposition of the dielectric layer 209.

Adverting to FIG. 2G, a photoresist 211 is formed on the dielectric layer 209 on the top surface of the glass substrate 201. Next, in FIG. 2H, the dielectric layer 209 is patterned to expose the metal layer 205 over the top surface of the TGV 203 and the area surrounding the TGV 203. Then, the photoresist 211 is removed. Next, in FIG. 21, Al or AlCu zincation is performed followed by formation of an ENIG layer 213. The zincation results in etching of thin Al or AlCu over the TGV thereby exposing non-sintered Cu/Ag particles. Then, the ENIG layer 213 is formed to a thickness of 1 to 2 micrometers (μm) on the metal layer over the top surface of the TGV 203 and the area surrounding the TGV 203. Although described as being on the top surface of the TGV, ENIG layer 213 can be formed on both the top and the bottom surfaces of the TGV 203 to reinforce the connections. The Ni reinforces the connections between the Al or AlCu and non-sintered Cu/Ag particles, thereby improving the electrical connection and reliability of the TGVs.

In the above embodiments, a TGV has been described as including one or more ENIG layers or multiple metal layers. Additional alternatives also include multiple metal layers formed on either one of the TGV surfaces and the ENIG layer formed on the other. Further, the additional alternatives also include the ENIG layer formed over the multiple metal layers formed on either one of the TGV surfaces.

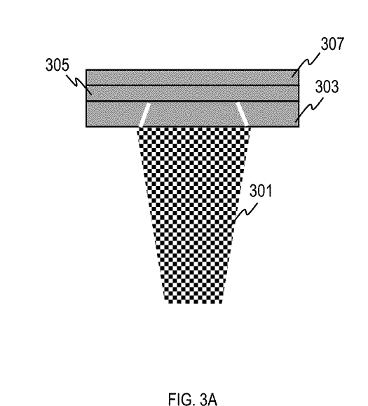

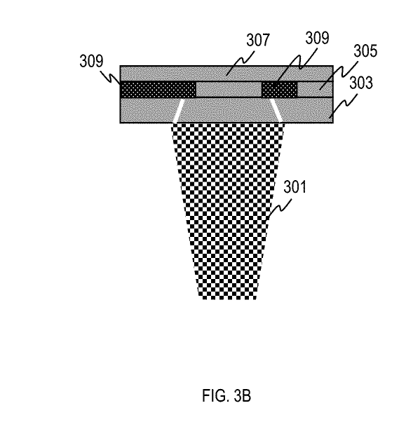

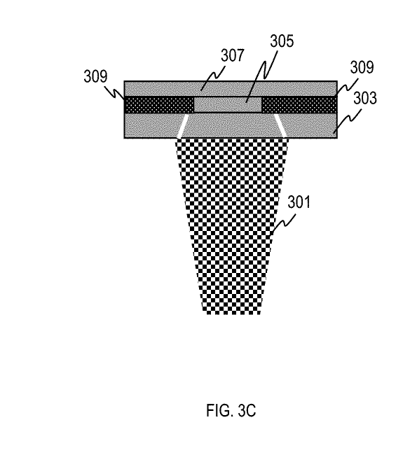

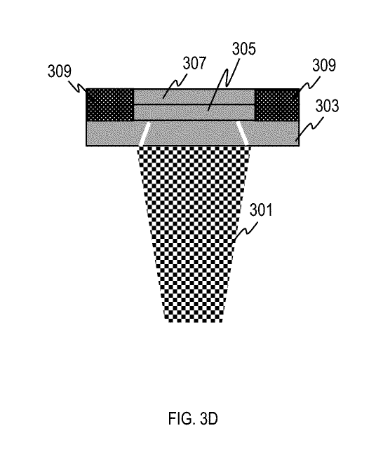

FIGS. 3A to 3D illustrate different embodiments of metal layers over a wide side of a TGV, in accordance with exemplary embodiments. Adverting to FIG. 3A, a TGV 301 filled with metal conductive paste is formed in a glass substrate. The TGV has a trapezoidal cross-section with a large end having a width of 15 μm to 100 μm located at the top surface of the glass substrate. A first metal layer 303 is formed to a thickness of 0.3 μm to 5 μm over the TGV. Next, a second metal layer 305 is formed to a thickness of 0.3 μm to 5 μm over the first metal layer 303. Subsequently, a third metal layer 307 is formed to a thickness of 0.3 μm to 5 μm over the second metal layer 305.

In FIG. 3B, a first metal layer 303 is formed to a thickness of 0.3 μm to 5 μm over a trapezoidal shaped TGV 301 with a large end having a width of 15 μm to 100 μm located at the top surface of the glass substrate. Then, a dielectric layer 309 is formed by PECVD to a thickness of 0.5 μm to 5 μm and a width of 1 μm to 100 μm or higher over the first metal layer 303. This dielectric layer 309 is patterned using photoresist to expose part of the first metal layer 303. Next, the photoresist is removed. Then, a second metal layer 305 is formed to a thickness of 0.3 μm to 5 μm over the first metal layer 303 and the dielectric layer 309. Next, a photoresist is formed on the second metal layer 305, and the second metal layer 305 is patterned. Next, the photoresist is removed. Next, a third metal layer 307 is formed to a thickness of 0.3 μm to 5 μm over the second metal layer 305 and the dielectric layer 309. As a result, the dielectric layer 309 is surrounded by the three metal layers.

In FIG. 3C, a first metal layer 303 is formed to a thickness of 0.3 μm to 5 μm over a trapezoidal shaped TGV 301 with a large end having a width of 15 μm to 100 μm located at the top surface of the glass substrate. Next, a dielectric layer 309 is formed by PECVD to a thickness of 0.5 μm to 5 μm and width of 1 μm to 100 μm or higher on the first metal layer 303. This dielectric layer 309 is patterned using photoresist to expose part of the first metal layer 303. Next, the photoresist is removed. Then, a second metal layer 305 is formed to a thickness of 0.3 μm to 5 μm over the first metal layer 303 and the dielectric layer 309. Next, a photoresist is formed on the second metal layer 305. Subsequently, the second metal layer 305 is patterned. Then, the photoresist is removed. Next, a third metal layer 307 is formed to a thickness of 0.3 μm to 5 μm over the second metal layer 305 and the dielectric layer 309. As a result, the dielectric layer 309 is formed between the first metal layer 303 and the third metal layer 307, and the second metal layer 305 is directly above the TGV 301 in a plain view.

In FIG. 3D, a first metal layer 303 is formed to a thickness of 0.3 μm to 5 μm over a trapezoidal shaped TGV 301 with a large end having a width of 15 μm to 100 μm located at the top surface of the glass substrate. Then, a dielectric layer 309 is formed by PECVD to a thickness of 0.5 μm to 5 μm and width of 1 μm to 100 μm or higher over the first metal layer 303. This dielectric layer 309 is patterned using photoresist to expose part of the first metal layer 303. Next, the photoresist is removed. Then, a second metal layer 305 is formed to a thickness of 0.3 μm to 5 μm over the first metal layer 303 and the dielectric layer 309. Next, a photoresist is formed on the second metal layer 305, and the second metal layer 305 is patterned. Subsequently, a third metal layer 307 is formed to a thickness of 0.3 μm to 5 μm over the second metal layer 305. Next, a photoresist is formed on the third metal layer 307, and the third metal layer 307 is patterned. Next, the photoresist is removed. As a result, the dielectric layer 309 is on the first metal layer 303 and surrounds the second metal layer 305 and the third metal layer 307.

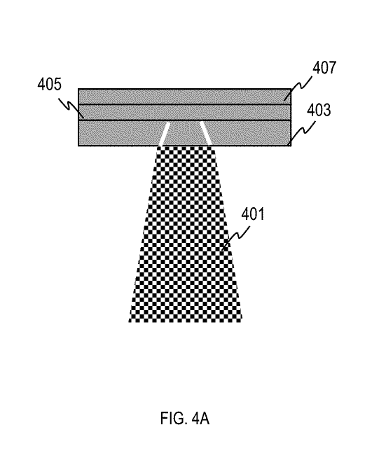

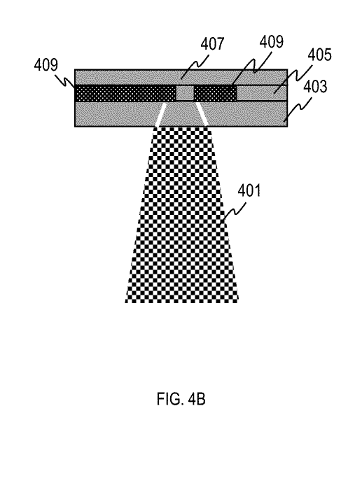

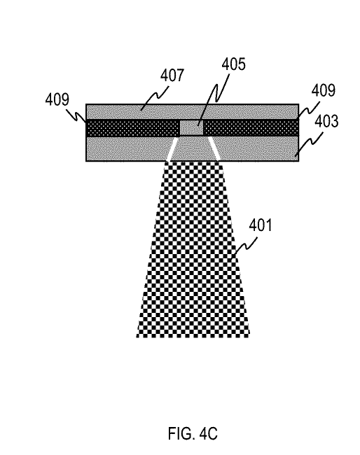

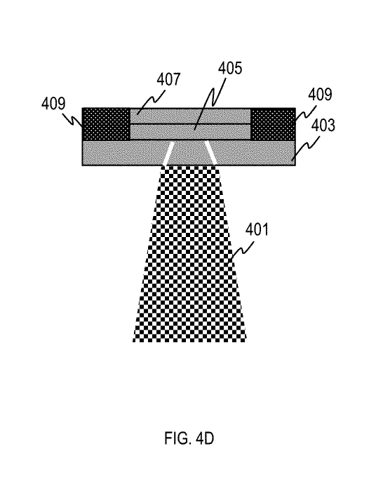

FIGS. 4A to 4D are different embodiments of metal layers over a small end of a TGV, in accordance with exemplary embodiments. Adverting to FIG. 4A, a TGV 401 filled with metal conductive paste is formed in a glass substrate. The TGV has a trapezoidal shape with a small end having a width of 10 μm to 95 μm located at the top surface of the glass substrate. A first metal layer 403 is formed to a thickness of 0.3 μm to 5 μm over the TGV. Next, a second metal layer 405 is formed to a thickness of 0.3 μm to 5 μm over the first metal layer 403. Subsequently, a third metal layer 407 is formed to a thickness of 0.3 μm to 5 μm over the second metal layer 405.

In FIG. 4B, a first metal layer 403 is formed to a thickness of 0.3 μm to 5 μm over a trapezoidal shaped TGV 401 with a small end having a width of 10 μm to 95 μm located at the top surface of the glass substrate. Then, a dielectric layer 409 is formed by PECVD to a thickness of 0.5 μm to 5 μm and a width of 1 μm to 100 μm or higher over the first metal layer 403. This dielectric layer 409 is patterned using photoresist to expose part of the first metal layer 403. Next, the photoresist is removed. Then, a second metal layer 405 is formed to a thickness of 0.3 μm to 5 μm over the first metal layer 403 and the dielectric layer 409. Next, a photoresist is formed on the second metal layer 405, and the second metal layer 405 is patterned. Next, the photoresist is removed. Then, a third metal layer 407 is formed to a thickness of 0.3 μm to 5 μm over the second metal layer 405 and the dielectric layer 409. As a result, the dielectric layer 409 is surrounded by the three metal layers.

In FIG. 4C, a first metal layer 403 is formed to a thickness of 0.3 μm to 5 μm over a trapezoidal shaped TGV 401 with a small end having a width of 10 μm to 95 μm located at the top surface of the glass substrate. Next, a dielectric layer 409 is formed by PECVD to a thickness of 0.5 μm to 5 μm and width of 1 μm to 100 μm or higher on the first metal layer 403. This dielectric layer 409 is patterned using photoresist to expose part of the first metal layer 403. Next, the photoresist is removed. Then, a second metal layer 405 is formed to a thickness of 0.3 μm to 5 μm over the first metal layer 403 and the dielectric layer 409. Next, a photoresist is formed on the second metal layer 405, and the second metal layer 405 is patterned. Then, the photoresist is removed. Next, a third metal layer 407 is formed to a thickness of 0.3 μm to 5 μm over the second metal layer 405 and the dielectric layer 409. As a result, the dielectric layer 409 is formed between the first metal layer 403 and the third metal layer 407, and the second metal layer 405 is directly above the TGV 401 in a plain view.

In FIG. 4D, a first metal layer 403 is formed to a thickness of 0.3 μm to 5 μm over a trapezoidal shaped TGV 401 with a small end having a width of 10 μm to 95 μm located at the top surface of the glass substrate. Then, a dielectric layer 409 is formed by PECVD to a thickness of 0.5 μm to 5 μm and width of 1 μm to 100 μm or higher over the first metal layer 403. This dielectric layer 409 is patterned using photoresist to expose part of the first metal layer 403. Next, the photoresist is removed. Then, a second metal layer 405 is formed to a thickness of 0.3 μm to 5 μm over the first metal layer 403 and the dielectric layer 409. Next, a photoresist is formed on the second metal layer 405, and the second metal layer 405 is patterned. Subsequently, a third metal layer 407 is formed to a thickness of 0.3 μm to 5 μm over the second metal layer 405. Next, a photoresist is formed on the third metal layer 407, and the third metal layer 407 is patterned. Next, the photoresist is removed. As a result, the dielectric layer 409 is on the first metal layer 403 and surrounds the second metal layer 405 and the third metal layer 407.

The embodiments of the present disclosure can achieve several technical effects, such as a robust and reliable interconnect structure for TGV. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure enjoys industrial applicability in any of various types of highly integrated finFET semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a through-glass-via (TGV) in a glass substrate, the glass substrate comprising borosilicate glass, boro-aluminosilicate glass, soda-lime glass, or photodefinable glass;
filling the TGV with a metal conductive paste;
forming a first metal layer on a top surface and a bottom surface of the glass substrate;
patterning the first metal layer, leaving at least a portion over a top surface of the TGV and an area surrounding the TGV;
forming a dielectric layer on the first metal layer and on the top and bottom surfaces of the glass substrate;
patterning the dielectric layer, including exposing the first metal layer over the top surface of the TGV and the area surrounding the TGV;
forming a second metal layer on the dielectric layer and on the exposed portion of the first metal layer over the top surface of the TGV and the area surrounding the TGV;
patterning the second metal layer to expose the dielectric layer; and
forming a third metal layer on the second metal layer.

2. A method according to claim 1, further comprising ashing prior to forming the first metal layer.

3. A method according to claim 1, comprising forming the first metal layer of aluminum (Al) or aluminum copper (AlCu) to a thickness of 0.3 micrometers (μm) to 5 μm.

4. A method according to claim 1, comprising forming the dielectric layer to a thickness of 0.5 μm to 5 μm.

5. A method according to claim 1 further comprising forming and patterning a second dielectric layer on the second metal layer prior to forming the third metal layer.

6. A method according to claim 1, comprising forming the metal conductive paste of a copper-silver (Cu—Ag) paste.

7. A method comprising:
forming a through-glass-vias (TGV) in a glass substrate, the glass substrate comprising borosilicate glass, boro-aluminosilicate glass, soda-lime glass, or photodefinable glass;
filling the TGV with a metal conductive paste;
forming a metal layer on a top surface and a bottom surface of the glass substrate;
patterning the metal layer, leaving at least a portion over a top surface of the TGV and an area surrounding the TGV;
forming a dielectric layer on the metal layer and on the top and bottom surfaces of the glass substrate;
patterning the dielectric layer, including exposing the metal layer over the top surface of the TGV and the area surrounding the TGV; and
forming an electroless nickel immersion gold (ENIG) layer on the metal layer over the top surface of the TGV and the area surrounding the TGV.

8. A method according to claim 7, further comprising ashing prior to forming the metal layer.

9. A method according to claim 7, comprising forming the metal layer of aluminum (Al) or aluminum copper (AlCu) to a thickness of 0.5 micrometers (μm) to 2 μm.

10. A method according to claim 9, further comprising Al or AlCu zincation prior to forming the ENIG layer.

11. A method according to claim 7, comprising forming the dielectric layer to a thickness of 0.5 μm to 5 μm.

12. A method according to claim 7, comprising forming the metal conductive paste of a copper-silver (Cu—Ag) paste.

13. A device comprising:
a through-glass-vias (TGV) filled with a metal conductive paste in a glass substrate;
a patterned first metal layer on a top surface and a bottom surface of the glass substrate, including at least a portion over a top surface of the TGV and an area surrounding the TGV;
a patterned dielectric layer on the first metal layer and the top surface and bottom surface of the glass substrate, the patterned dielectric layer including an opening over the top surface of the TGV and the area surrounding the TGV, exposing the first metal layer; and
a second metal layer and a third metal layer or an electroless nickel immersion gold (ENIG) layer on the first metal layer.

14. A device according to claim 13, wherein the first metal layer comprises aluminium (Al) and has a thickness of 0.3 micrometers (μm) to 5 μm and the second and third metal layers are formed on the first metal layer.

15. A device according to claim 14, wherein the second and third metal layers each have a thickness of 0.3 μm to 5 μm.

16. A device according to claim 13, further comprising:
the second and third metal layers or the ENIG layer formed over a bottom surface of the TGV and the area surrounding the TGV.

17. A device according to claim 13, wherein the ENIG layer is formed on the first metal layer, and the first metal layer comprises zincated aluminum (Al) or zincated aluminum copper (AlCu).

18. A device according to claim 17, wherein the first metal layer has a thickness of 0.5 micrometer (μm) to 2 μm.

19. A device according to claim 17, wherein the ENIG layer has a thickness of 1 μm to 2 μm.

20. A device according to claims 13, further comprising:
an ENIG layer formed over the second and third metal layers either on the top or a bottom surface of the TGV.
